(19) United States
(12) Patent Application Publication
(10) Pub. No.: US 2006/0125659 A1
(43) Pub. Date: Jun. 15, 2006

(54) Text input method and apparatus using bio-signals

(75) Inventors: Ki Hong Kim, Daejeon-city (KR); Hong Kee Kim, Daejeon-city (KR); Jong Sung Kim, Daejeon-city (KR); Wookho Son, Daejeon-city (KR); Hyun Bin Kim, Daejeon-city (KR)

Correspondence Address: MAYER, BROWN, ROWE & MAW LLP, 1909 K STREET, N.W., WASHINGTON, DC, 20006, US

(73) Assignee: ELECTRONICS AND TELECOMMUNICATIONS RESEARCH INSTITUTE

(21) Appl. No.: 11/152,100

(22) Filed: Jun. 15, 2005

(30) Foreign Application Priority Data
Dec. 13, 2004 (KR) 10-2004-0104920

(51) Int. Cl. H03K 17/94; G06F 17/00; G09B 21/00

(52) U.S. Cl. 341/20; 340/825.19; 715/773

(57) ABSTRACT

A method and apparatus for inputting text, by dividing the letter arrangement on a keyboard by area, providing the divided letter arrangement areas on the screen, and making letters be selected step by step according to the bio-signal of a user, are provided. The text input apparatus using a bio-signal includes: a sensor detecting a bio-signal of a human being; a bio-signal measuring unit analyzing the detected bio-signal and extracting characteristic information; and an instruction generation unit converting the characteristic information into an instruction used to drive an application program, according to a preset mapping relation prepared corresponding to the extracted characteristic information. According to the method and apparatus, communications by users, who cannot practically use conventional interfaces, such as a mouse and a keyboard and therefore, experience difficulties in communicating with others in a computing environment, can be easily performed.

### CROSS-REFERENCE TO RELATED PATENT APPLICATIONS

This application claims the benefit of Korean Patent Application No. 10-2004-0104920, filed on Dec. 13, 2004, in the Korean Intellectual Property Office, the disclosure of which is incorporated herein in its entirety by reference.

### BACKGROUND OF THE INVENTION

1. Field of the Invention

The present invention relates to text input using a bio-signal, and more particularly, to a method and apparatus for inputting text, by dividing the letter arrangement on a keyboard by area, providing the divided letter arrangement areas on the screen, and making letters be selected step by step according to the bio-signal of a user.

2. Description of the Related Art

In order to transmit email or to perform word processing by using a computer, text data should be input by using input apparatuses such as a keyboard and a mouse. However, disabled persons who have problems in using hands or have paralyzed hands and therefore have difficulties in using these letter input apparatuses should use other input devices. Physically disabled persons cannot use the text input apparatuses using hands, and can use text by using speech recognition or using a bio-signal. For example, there may be a method by which a virtual keyboard is generated and shown on the screen, and the user can select and input a letter by using an appropriate physical means. At this time, what can be used as a bio-signal includes a muscle signal and a brain wave. In order to receive a muscle signal or a brain wave, determine which letter is input, and input the letter in a computer, a variety of processes, including sensing the signal, analog-digital conversion, and signal processing, should be performed. Though text can be input by a speech recognition method, if there is a problem in pronunciation, it is also difficult to use this method.

In the conventional technologies, disclosed are only the text input method according to the speech recognition method, the method for manipulating a computer by using a bio-signal and the like. However, a method for selecting a desired letter quickly and generating and inputting text is not disclosed.

### SUMMARY OF THE INVENTION

The present invention provides a method and apparatus for inputting a letter by using a bio-signal, by which when an input apparatus such as a keyboard cannot be used, a letter arrangement such as a keyboard is generated and provided on a screen, and according to an instruction related to a direction manipulation generated by the body motion of a user, a letter is quickly selected such that the disabled user can transmit email, perform word processing, and electronic commerce using the Internet.

According to an aspect of the present invention, there is provided a text input apparatus including: a sensor detecting a bio-signal of a human being; a bio-signal measuring unit analyzing the detected bio-signal and extracting characteristic information; and an instruction generation unit converting the characteristic information into an instruction used to drive an application program, according to a preset mapping relation prepared corresponding to the extracted characteristic information.

The sensor may detect a bio-signal having a predetermined pattern capable of being made to correspond to an instruction that is used to drive the application program.

The apparatus may further include a keyboard screen display unit wherein letters arranged on the keyboard are disposed in a plurality of divided areas and the instruction selects one of the divided areas, and again selects a sub-area in the selected area such that a letter desired by the user is selected.

According to another aspect of the present invention, there is provided a text input method including: detecting a bio-signal of a human being; analyzing the detected bio-signal, extracting characteristic information, and then, converting the characteristic information into an instruction used to drive an application program, according to a preset mapping relation prepared corresponding to the extracted characteristic information; and by performing the instruction, selecting one of divided areas on a keyboard and selecting again a sub-area in the selected area so that a letter is selected.

According to still another aspect of the present invention, there is provided a text input method including: receiving a signal to select one area on a keyboard screen in which letters are arranged in a plurality of divided areas, according to a bio-signal; and receiving a signal selecting one sub-area in a plurality of divided sub-areas in the selected area, according to a bio-signal.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic diagram of the structure of a system driving an email program through a text input apparatus providing a keyboard screen and receiving a letter input according to the bio-signal of a user according to a preferred embodiment of the present invention;

FIGS. 2A through 2F are diagrams showing a process for inputting a letter according to a text input method using a bio-signal according to a preferred embodiment of the present invention; and

FIG. 3 is a flowchart of the operations performed by a text input method using a bio-signal according to a preferred embodiment of the present invention.

### DETAILED DESCRIPTION OF THE INVENTION

The present invention will now be described more fully with reference to the accompanying drawings, in which exemplary embodiments of the invention are shown.

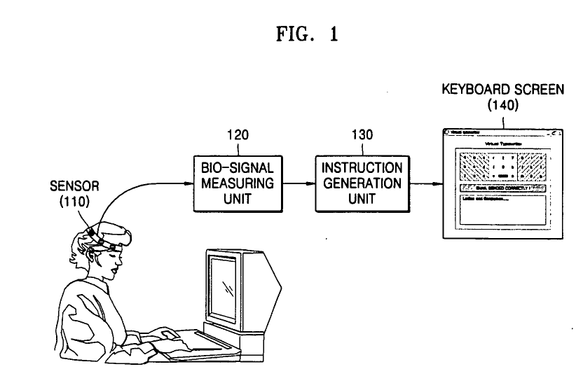

Referring to FIG. 1, the text input apparatus using a bio-signal includes a sensor 110, a bio-signal measuring unit 120, and an instruction generation unit 130, and an email program provides a keyboard screen 140 to the user. The sensor 110 detects a variety of bio-signals of a human being. The bio-signal that is detected by the sensor 110 includes signals having a variety of patterns that can correspond to instructions to be used to drive the email program, for example, a brain wave, or a muscle signal such as eye blinking and teethridge motion. For example, a variety of instructions can be made to correspond to the frequency of eye blinking or intervals of eye blinking. By using the bio-signal having this variety of patterns, a variety of instructions are mapped.

The bio-signal measuring unit 120 converts the detected bio-signal into a digital value, analyzes the value, extracts characteristic information, and outputs the information to the instruction generation unit 130. If the value measured in the sensor 110 is small, the bio-signal measuring unit 120 can amplify the value. Also, the bio-signal measuring unit 120 and the instruction generation unit 130 can be implemented as programs or as independent hardware modules. The instruction generation unit 130 converts the detected bio-signal into an instruction. For example, if eyes blink once, it is recognized as clicking enter button, or if eyes blink twice, it is recognized as clicking selection button. Thus, one instruction is made to correspond to a pattern of the bio-signal. The keyboard screen 140 displays a letter selected by the user according to the instruction output by the instruction generation unit 130.

At this time, the keyboard screen 140 is a graphic user interface implementing by software, a keyboard arrangement similar to the keyboard used as an input apparatus of a computer system. Also, according to two modes, Korean and English modes, a keyboard arrangement of a different language is displayed. In addition, there are some more keys required depending on application programs. The user selects one key among thus provided keys, by using a bio-signal, and inputs it to the computer.

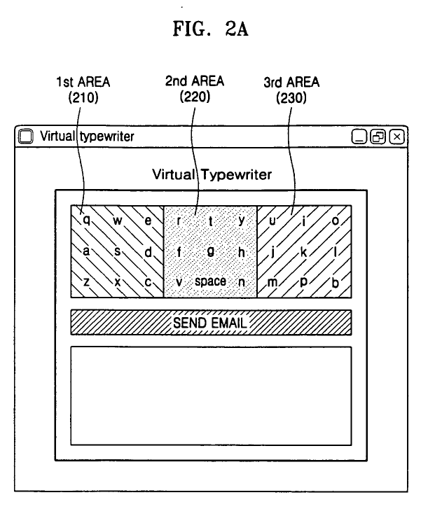

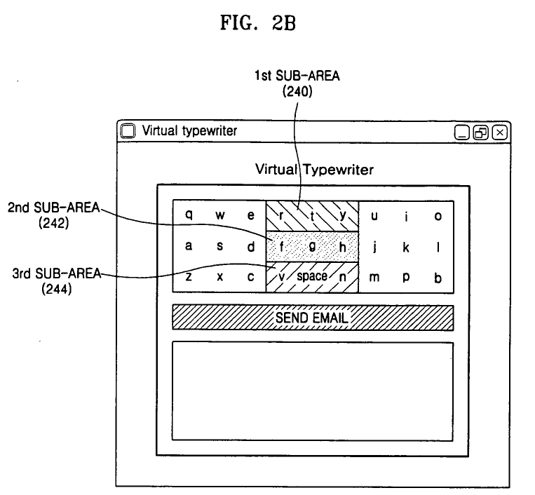

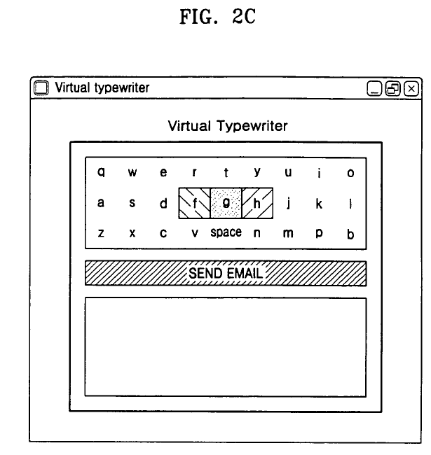

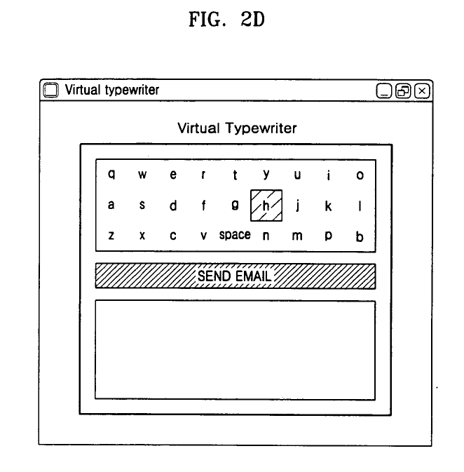

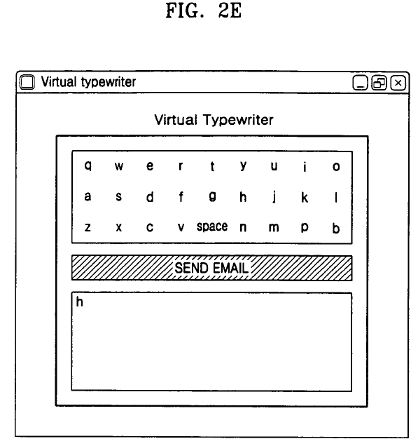

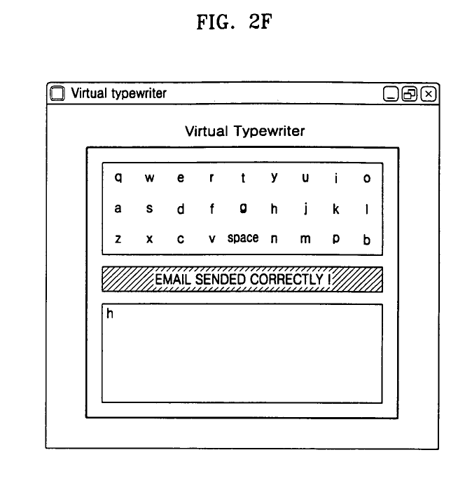

FIGS. 2A through 2F are diagrams showing a process for inputting a letter according to a text input method using a bio-signal according to a preferred embodiment of the present invention.

Referring to FIG. 2A, it can be seen that letters arranged on the virtual keyboard screen are divided into three areas, a first area 210, a second area 220, and a third area 230. Accordingly, the user first selects an area, and by repeating the process to determine an area in the selected area and selecting the area, the user can easily input a letter. For example, when letter ‘h’ is desired to be typed, the virtual keyboard screen as shown in FIG. 2A is provided on the monitor. Since letter ‘h’ desired to be typed is in the second area 220 among the three areas 210 through 230, the user first selects the second area 220. Selection of the second area 220 is performed through a bio-signal.

More specifically, selection of an area is performed as described above, by an instruction obtained after sensing a bio-signal such as an electromyogram and a brain wave, and analyzing the signal through an appropriate signal processing algorithm. Referring to FIG. 2A, since there are three areas in total, there are 5 instructions, including three directional movement instructions, ‘move left,’ ‘move right’, and ‘move to the center’, and ‘confirm’ corresponding to confirmation of a selected area, and ‘send’ required to send email. In case of email application programs, instruction ‘send’ is required. However, since the present invention is not limited to email application programs and can be applied to a variety of application programs requiring text inputs, more instructions can be further used depending on application programs.

Patterns of a bio-signal to be mapped on the instructions will now be explained with examples. It is assumed that a muscle signal generated when the user clenches left molar teeth is mapped to ‘move left’, a muscle signal generated when the user clenches right molar teeth is mapped to ‘move right’, a muscle signal generated when the user clenches both side molar teeth is mapped to ‘move to the center’, a muscle signal generated when the user blinks eyes is mapped to ‘confirm’ and a muscle signal generated when the user blinks eyes twice is mapped to ‘send’.

Meanwhile, on the virtual keyboard screen, in order for the user to be able to select a letter more quickly, letters are divided into three areas, and the second area 220, that is, the central area, is indicated in advance as a default area. Accordingly, since the example letter ‘h’ is in the central area, movement to the left or to the right is not needed, and the user can perform clenching of both side molar teeth that corresponds to instruction ‘move to the center’, in order to select the central area.

If letter ‘a’ is desired to be selected, the user should select the first area 210 on the left hand side of the three areas. Accordingly, in order to generate a bio-signal corresponding to instruction ‘move left’, by performing clenching of left molar teeth, the first area 210 is selected. Then, in order to indicate that the selection is correct one, to the system, the motion of blinking eyes twice corresponding to instruction ‘confirm’ is performed. The reason for performing this confirmation is to select an area again when an undesired area is selected. That is, if the user mistakenly selects an undesired area, an area can be selected again without performing the motion for ‘confirm’ and by generating a bio-signal corresponding to ‘move left’ or ‘move right’. Then, by the motion corresponding to instruction ‘confirm’, it is finally determined that the area is a desired one by the user. Accordingly, until the motion for ‘confirm’ is performed, it cannot be said that a desired area is selected.

If the second area 220 that is the central area containing letter ‘h’ among the three areas shown in the initial screen is selected in this manner, the second area 220 in the virtual keyboard is activated as shown in FIG. 2B, and the second area 220 is further divided into three areas 240, 242, and 244, and shown to the user. In this level, three letters, ‘r’, ‘t’, ‘y’, corresponding to a first sub-area 240 are selected in response to instruction ‘move left’ described above, three letters, ‘v’, ‘Space’, and ‘n’, corresponding to a third sub-area 244 are selected in response to instruction ‘move right’, and three letters, ‘f’, ‘g’, and ‘h’, corresponding to a second sub-area 242 are selected in response to instruction ‘move to the center’. Meanwhile, in the initial stage of this level, the second-sub area 242 is selected as a default. Then, since letter ‘h’ is in the second sub-area 242, the motion corresponding to instruction ‘move to the center’ is performed such that the second sub-area 242 is selected.

As a result, three letters are left in the second sub-area 242 as shown in FIG. 2C. Accordingly, while the second sub-area 242 is activated and shown to the user, letter ‘g’ at the center is indicated by a selected position internally as a default. Since ‘h’ is located on the right hand side in this second sub-area 242, in order to generate an instruction corresponding to ‘move right’, the user performs the motion of clenching of right molar teeth to select ‘h’. If letter ‘h’ is thus selected as shown in FIG. 2D, motion for ‘confirm’ indicating that a correct area is selected is performed such that letter ‘h’ is finally typed in and is displayed in the message box as shown in FIG. 2E.

Though an example of selecting and typing a desired letter is explained above, a sentence desired to be transmitted to a destination can be completed by repeating the process described above. Once a sentence is completed, email is sent. For this, continuous twice eye blinking, the motion corresponding to instruction ‘send’, is performed to execute the instruction. FIG. 2F shows that email is being sent by the operation of a key corresponding to ‘send email’, assuming that a sentence is completed. If the email is correctly sent, the result message is output on the screen.

Thus, by performing motions, only six times, corresponding to instructions mapped in advance, the user can type a desired letter. For example, letter ‘g’ is input according to ‘move to the center’->‘confirm’->‘move to the center’->‘confirm’->‘move to the center’->‘confirm’, and letter ‘z’ is input according to ‘move left’->‘confirm’->‘move right’->‘confirm’->‘move left’->‘confirm’.

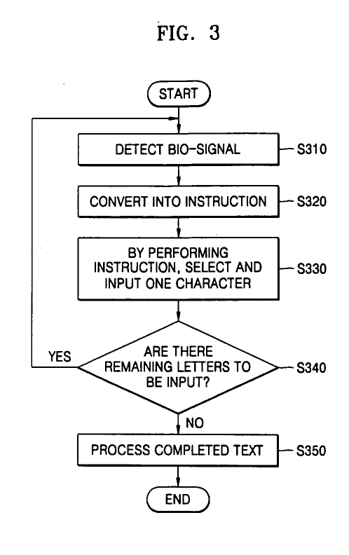

FIG. 3 is a flowchart of the operations performed by a text input method using a bio-signal according to a preferred embodiment of the present invention.

When a keyboard screen is provided to the user, the user performs a motion to select a letter on the keyboard. An example of the motion includes the motion for movement instructions corresponding to direction keys described above, and the motions are set in the system in advance. If the user performs the thus set motion and generates a bio-signal, the sensor detects this signal in operation S310. With the detected signal, the pattern of the signal is identified and converted into an instruction in operation S320. As described above, instructions include ‘move left’, ‘move right’, or ‘select’, and the detected bio-signal includes a brain wave signal, a motion of an eyeball, and a teethridge compression signal. Then, by performing the converted instruction, an area distinguished in the keyboard screen is selected, and in the selected area, a sub-area is again selected such that one letter is selected and input in operation S330.

Thus, letters on the virtual keyboard are divided into a variety of areas and by repeating selection of an area, a letter is typed in. It is determined whether or not there are remaining letter desired to be input in operation S340, and if letters should be further input in order to make a sentence, the operations from S310 are repeated. If a sentence is finally completed, instruction such as ‘send email’ or ‘store sentence’ is performed to process the completed text in operation S350.

Meanwhile, the text input method described above can be implemented as a computer program. Codes and code segments forming the program can be easily inferred by the programmers in the technology field of the present invention. Also, the program is stored in computer readable media, and read and executed by a computer to implement the text input method. The computer readable media includes magnetic recording media, optical recording media and carrier wave media.

While the present invention has been particularly shown and described with reference to exemplary embodiments thereof, it will be understood by those of ordinary skill in the art that various changes in form and details may be made therein without departing from the spirit and scope of the present invention as defined by the following claims. The preferred embodiments should be considered in descriptive sense only and not for purposes of limitation. Therefore, the scope of the invention is defined not by the detailed description of the invention but by the appended claims, and all differences within the scope will be construed as being included in the present invention.

According to the present invention as described above, the method and apparatus can be used when disabled persons who have problems in using hands or have paralysed hands use a letter input system such as an email system. The method and apparatus also enable easier communications by those who cannot practically use the conventional interface, such as a mouse and a keyboard, and therefore experience difficulties in communications with others. In addition, when a desired letter is typed in, the letter can be selected with the least number of motions.

What is claimed is:

1. A text input apparatus comprising:
a sensor detecting a bio-signal of a human being;
a bio-signal measuring unit analyzing the detected bio-signal and extracting characteristic information; and
an instruction generation unit converting the characteristic information into an instruction used to drive an application program, according to a preset mapping relation prepared corresponding to the extracted characteristic information.

2. The apparatus of claim 1, wherein the sensor detects a bio-signal having a predetermined pattern capable of being made to correspond to an instruction that is used to drive the application program.

3. The apparatus of claim 1, further comprising:
a keyboard screen display unit wherein letters arranged on the keyboard are disposed in a plurality of divided areas and the instruction selects one of the divided areas, and again selects a sub-area in the selected area such that a letter desired by the user is selected.

4. The apparatus of claim 1, wherein the application program is a program requiring a text input and includes an email program.

5. A text input method comprising:
detecting a bio-signal of a human being;
analyzing the detected bio-signal, extracting characteristic information, and then, converting the characteristic information into an instruction used to drive an application program, according to a preset mapping relation prepared corresponding to the extracted characteristic information; and
by performing the instruction, selecting one of divided areas on a keyboard and selecting again a sub-area in the selected area so that a letter is selected.

6. The method of claim 5, wherein
one area is selected according to a selection area movement instruction.

7. A text input method comprising:
receiving a signal to select one area on a keyboard screen in which letters are arranged in a plurality of divided areas, according to a bio-signal; and
receiving a signal selecting one sub-area in a plurality of divided sub-areas in the selected area, according to a bio-signal.

8. The method of claim 7, further comprising:
receiving a signal selecting one of letters included in the selected sub-area and finally selecting and displaying one letter.
